(19) United States
(12) Patent Application Publication
(10) Pub. No.: US 2026/0243808 A1
(43) Pub. Date: Aug. 20, 2026

(54) WEIGHTED LOCK-IN DETECTOR

(71) Applicant: Government of the United States of America, as represented by the Secretary of Commerce, Gaithersburg, MD (US)

(72) Inventors: Yicheng Wang, Germantown, MD (US); Stephan Schlamminger, Silver Spring, MD (US)

(21) Appl. No.: 19/543,032

(22) Filed: Feb. 18, 2026

Related U.S. Application Data
(60) Provisional application No. 63/759,670, filed on Feb. 18, 2025.

(51) Int. Cl. G01R 19/10; G01R 17/02; G01R 19/00

(52) U.S. Cl. CPC G01R 19/10; G01R 17/02; G01R 19/0007; G01R 19/0053

(57) ABSTRACT

A weighted lock-in detector for signals with arbitrary phase differences includes a first detection circuit including a first amplifier and a first phase sensitive detector; a second detection circuit including a second amplifier and a second phase sensitive detector; and a correlator configured to linearly combine with complex coefficients output signals of the first and second detection circuits, thereby measuring a difference in amplitude between first and second input signals to the respective detection circuits.

### RELATED APPLICATIONS

This application claims the benefit of U.S. Provisional Patent Application Ser. No. 63/759,670 (filed Feb. 18, 2025), which is hereby incorporated herein by reference in its entirety.

### FEDERALLY-SPONSORED RESEARCH AND DEVELOPMENT

This invention was made with United States Government support from the National Institute of Standards and Technology (NIST), an agency of the United States Department of Commerce. The Government has certain rights in this invention.

### COPYRIGHT NOTICE

This patent disclosure may contain material that is subject to copyright protection. The copyright owner has no objection to the facsimile reproduction by anyone of the patent document or the patent disclosure as it appears in the U.S. Patent and Trademark Office patent file or records, but otherwise reserves any and all copyright rights.

### FIELD OF INVENTION

The present invention relates generally to lock-in detectors, and more particularly to a weighted lock-in detector that operates with arbitrary phase differences.

### BACKGROUND

A lock-in detector, also known as a lock-in amplifier, is a device that measures the amplitude and phase of a signal at a specific frequency. It's used to detect small signals in the presence of noise. A lock-in amplifier multiplies the input signal by a reference signal. The reference signal frequency and the modulation frequency of the experiment are set to be equal. A low-pass filter is applied to the result. The low-pass filter rejects noise signals at frequencies other than the reference frequency.

### SUMMARY OF INVENTION

A conventional lock-in detector has two inputs (A and B) and can be used either in the single-ended input mode (with B grounded) or in the differential input mode (A-B). The differential mode does not work when the A and B input signals have different phases. Therefore, presented herein is a new weighted lock-in detector that also has two inputs, but it works when the A and B input signals have an arbitrary phase difference. The detector output is a linear combination with complex coefficients of the two detector inputs. This invention has been demonstrated with a digital four-arm bridge. The diamond-shaped four-arm bridge has two detection nodes where the error signals are at approximately 90 degrees for the comparison of capacitance with resistance. Exemplary embodiments may include a lock-in with an arbitrary number of channels with individual complex weighing factors.

According to one aspect of the invention, weighted lock-in detector for signals with arbitrary phase differences includes a first detection circuit including a first amplifier and a first phase sensitive detector; a second detection circuit including a second amplifier and a second phase sensitive detector; and a correlator configured to linearly combine with complex coefficients output signals of the first and second detection circuits, thereby measuring a difference in amplitude between first and second input signals to the respective detection circuits.

Optionally, the weighted lock-in detector includes an arbitrary number of channels with individual complex weighing factors.

Optionally, the weighted lock-in detector includes a third detection circuit including a third amplifier and a third phase sensitive detector, and wherein the correlator is configured to linearly combine with complex coefficients output signals of the first, second, and third detection circuits, thereby measuring a difference in amplitude between each pair of input signals to the respective detection circuits.

According to another aspect of the invention, a four-arm bridge includes a first detector node; a second detector node; a weighted lock-in detector having a first detection circuit electrically coupled to the first detector node, a second detection circuit electrically coupled to the second detector node, and a correlator configured to linearly combine with complex coefficients output signals of the first and second detection circuits, thereby measuring a difference in amplitude between first and second input signals to the respective detection circuits.

According to another aspect of the invention, a method of lock-in detection for signals having an arbitrary phase difference includes simultaneously detecting a first input signal and a second input signal through respective detection circuits, generating respective detected signals; and combining the detected signals linearly with complex coefficients by a correlator, generating an output signal.

Optionally, the output measures difference in amplitude between the first and second input signals and retains common-mode rejection regardless of any phase difference between the first and second input signals.

Optionally, detecting a first input signal includes detecting a signal from a first side of a four-arm bridge, detecting a second signal includes detecting a signal from a second side of the four-arm bridge, and wherein the signal from the first side of a four-arm bridge and the signal from the second side of the four-arm bridge are out of phase by approximately 90 degrees.

The foregoing and other features of the invention are hereinafter described in greater detail with reference to the accompanying drawings.

### BRIEF DESCRIPTION OF THE DRAWINGS

FIG. 1 shows a schematic diagram of an exemplary lock-in detector.

FIG. 2 shows a schematic diagram of a conventional lock-in detector.

FIG. 3 shows a schematic diagram of an exemplary lock-in detector being used in a four-arm bridge.

FIG. 4 shows a block diagram of an exemplary method of lock-in detection.

### DETAILED DESCRIPTION

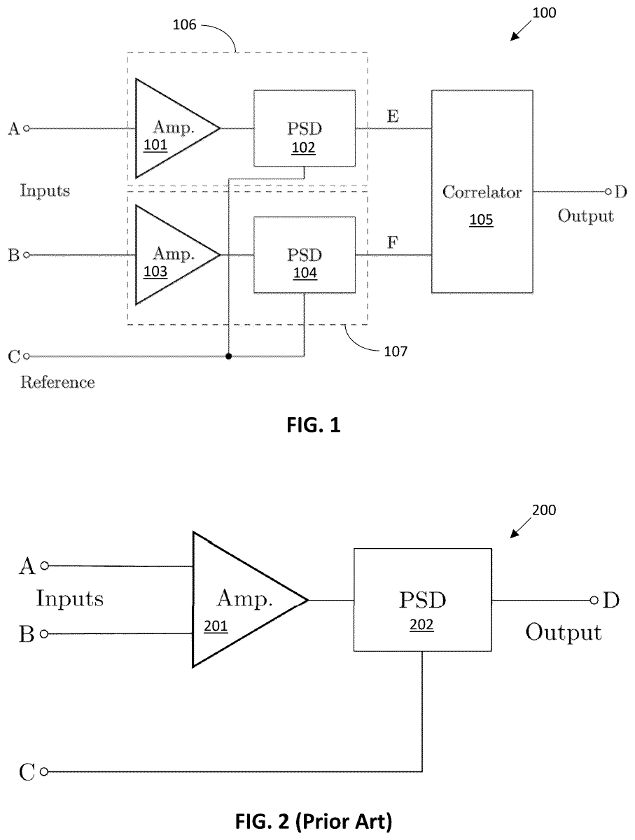

Disclosed herein is a weighted lock-in detector 100: a type of detector that can extract a signal with a known frequency from an extremely noisy environment. Referring first to FIG. 1, the weighted lock-in detector 100 includes a second detection circuit 107 (including an amplifier 103 and a phase sensitive detector (PSD) 104) added to a first detection circuit 106 (including an amplifier 101 and a PSD 102) used in conventional lock-in detectors. The amplifier (103 and 101) represents a linear analog circuit that amplifies an input signal, whose strength may vary widely from one application to another, to a suitable level for the subsequent phase sensitive detection. The PSD (104 and 102) performs a multiplication of its input with a reference signal, also sometimes called mixing or homodyne detection, which can be implemented with analog techniques, digital techniques, software techniques, or a mixture of the three techniques. A correlator 105 is then used to linearly combine with complex coefficients of the two output signals (E and F) of the two detection circuits. The output of the correlator 105, (D), measures the difference in amplitude of the two input signals (A and B).

The input signal, A, is amplified through the amplifier 101 and then detected by the PSD 102, in reference to the reference input, (C). The input signal, (B), is amplified through the amplifier 103 and then detected by the PSD 104, in reference to the reference input, (C). The two detected signals (E and F) are then linearly combined with complex coefficients by the correlator 105 to generate the output (D) that measures the difference in amplitude of the two input signals (A and B).

One key distinguishing feature between the subject invention and a conventional lock-in detector is the addition of a second detection circuit 107 (comprising amplifier 103 and PSD 104), which allows simultaneous but separate detections of the two input signals (A and B) and subsequent linear combination with complex coefficients of the two detected signals (E and F) by the correlator 105 to generate the output (D) that measures the difference in amplitude of the two input signals (A and B).

FIG. 2 shows a typical representation of conventional lock-in detector at 200. The lock-in detector 200 has an amplifier 201, a PSD 202, and two inputs (A and B) and can be used either in the single-ended input mode (with B grounded) or in the differential input mode (A-B). The differential mode requires the input signals (A and B) to have the same phase in order to measure their difference in amplitude:

$$A = {A}_{o} {e}^{- i ( ω t + φ )} \qquad ( 1 )$$

$$B = {B}_{o} {e}^{- i ( ω t + φ )} ,$$

where ω is the angular frequency, Aₒ and φ are the amplitude and the phase, respectively, of the input signal A, and Bₒ and φ are the amplitude and the phase, respectively, of the input signal B. The general output of the PSD 202 is:

$$D = {D}_{o} {e}^{- i φ} , \qquad ( 2 )$$

where Dₒ=Aₒ−Bₒ. In practice, the phase of the input signals (A and B) can be aligned with that of the reference input (C) such that φ=0. Thus, the output (D) measures the difference in amplitude of the two input signals (A and B) directly and any common-mode fluctuations of the input signals cancel out, which is known as the common-mode rejection.

A commercial lock-in detector as represented in FIG. 2 does not have the common-mode rejection when there is a phase difference, Δ, between the two input signals (A and B):

$$A = {A}_{o} {e}^{- i ( ω t + φ )} \qquad ( 3 )$$

$$B = {B}_{o} {e}^{- i ( ω t + φ + Δ )} .$$

As shown in FIG. 4, method 400 and other embodiments of the invention overcome this shortcoming by, at block 410, first simultaneously detecting the two input signals (A and B) through two separate detection circuits (106 and 107) to generate the two detected signals:

$$E = {A}_{o} {e}^{- i φ} \qquad ( 4 )$$

$$F = {B}_{o} {e}^{- i ( φ + Δ )} .$$

At block 420, exemplary embodiments may subsequently combine linearly with complex coefficients of the two detected signals (E and F) by the correlator 105 to generate the output:

$$D = {ρ}_{1} E + {ρ}_{2} F = {D}_{o} {e}^{- i φ} \qquad ( 5 )$$

where Dₒ=Aₒ−Bₒ, ρ₁=1, and ρ₂=e^{jΔ}, is determined by the correlator 105 through correlation analysis of the two detected signals (E and F). φ=0 is achieved by aligning the phase of the input signal (A) with that of the reference input (C). Thus, the output (D) of the weighted lock-in detector measures the difference in amplitude of the two input signals (A and B) and retains the common-mode rejection despite there is a phase difference between the two input signals (A and B).

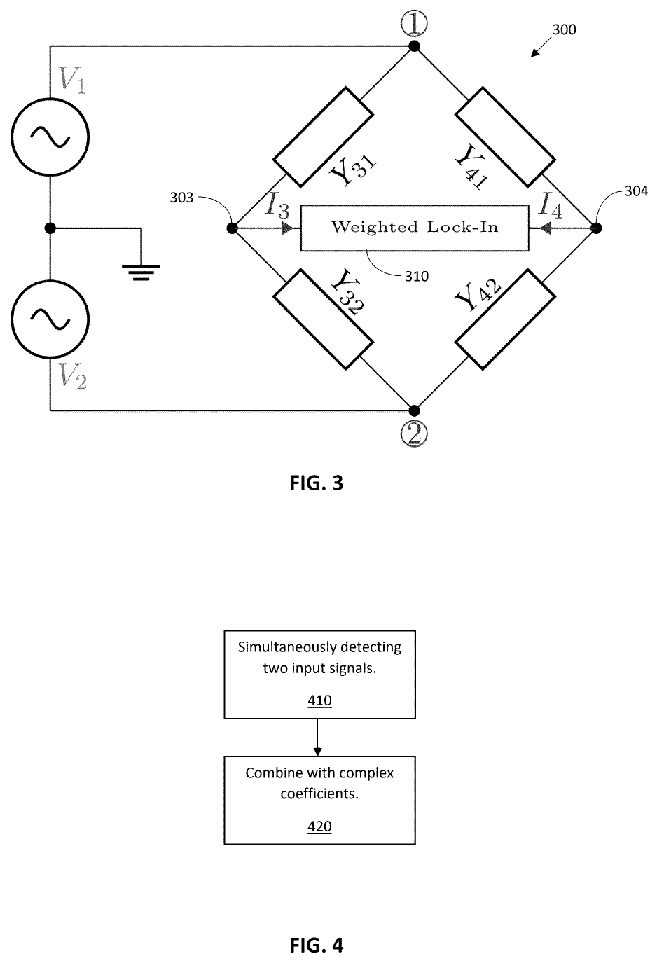

FIG. 3 shows an exemplary lock-in detector 310 as the null detector of a four-arm bridge 300 configured for the comparison of resistance with capacitance. The two input terminals (A and B) of the lock-in detector are connected to the detector nodes, 303 and 304, of the bridge network. There is a phase difference, approximately 90°, between the two input signals (A and B), but the lock-in detector 310 retains the common-mode rejection that a conventional lock-in detector would have in a conventional four-arm bridge. Here, the weighted lock-in detector 310 measures the difference in amplitude of the two input signals (A and B) with their phase difference being compensated by the correlator 105.

The processes described herein may be embodied in, and fully automated via, software code modules executed by a computing system that includes one or more general purpose computers or processors. The code modules may be stored in any type of non-transitory computer-readable medium or other computer storage device. Some or all the methods may alternatively be embodied in specialized computer hardware. In addition, the components referred to herein may be implemented in hardware, software, firmware, or a combination thereof.

Many other variations than those described herein will be apparent from this disclosure. For example, depending on the embodiment, certain acts, events, or functions of any of the algorithms described herein can be performed in a different sequence, can be added, merged, or left out altogether (e.g., not all described acts or events are necessary for the practice of the algorithms). Moreover, in certain embodiments, acts or events can be performed concurrently, e.g., through multi-threaded processing, interrupt processing, or multiple processors or processor cores or on other parallel architectures, rather than sequentially. In addition, different tasks or processes can be performed by different machines and/or computing systems that can function together.

Any logical blocks, modules, and algorithm elements described or used in connection with the embodiments disclosed herein can be implemented as electronic hardware, computer software, or combinations of both. To clearly illustrate this interchangeability of hardware and software, various illustrative components, blocks, modules, and elements have been described above generally in terms of their functionality. Whether such functionality is implemented as hardware or software depends upon the particular application and design constraints imposed on the overall system. The described functionality can be implemented in varying ways for each particular application, but such implementation decisions should not be interpreted as causing a departure from the scope of the disclosure.

The various illustrative logical blocks and modules described or used in connection with the embodiments disclosed herein can be implemented or performed by a machine, such as a processing unit or processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A processor can be a microprocessor, but in the alternative, the processor can be a controller, microcontroller, or state machine, combinations of the same, or the like. A processor can include electrical circuitry configured to process computer-executable instructions. In another embodiment, a processor includes an FPGA or other programmable device that performs logic operations without processing computer-executable instructions. A processor can also be implemented as a combination of computing devices, e.g., a combination of a DSP and a microprocessor, a plurality of microprocessors, one or more microprocessors in conjunction with a DSP core, or any other such configuration. Although described herein primarily with respect to digital technology, a processor may also include primarily analog components. For example, some or all of the signal processing algorithms described herein may be implemented in analog circuitry or mixed analog and digital circuitry. A computing environment can include any type of computer system, including, but not limited to, a computer system based on a microprocessor, a mainframe computer, a digital signal processor, a portable computing device, a device controller, or a computational engine within an appliance, to name a few.

The elements of a method, process, or algorithm described in connection with the embodiments disclosed herein can be embodied directly in hardware, in a software module stored in one or more memory devices and executed by one or more processors, or in a combination of the two. A software module can reside in RAM memory, flash memory, ROM memory, EPROM memory, EEPROM memory, registers, hard disk, a removable disk, a CD-ROM, or any other form of non-transitory computer-readable storage medium, media, or physical computer storage known in the art. An example storage medium can be coupled to the processor such that the processor can read information from, and write information to, the storage medium. In the alternative, the storage medium can be integral to the processor. The storage medium can be volatile or nonvolatile.

While one or more embodiments have been shown and described, modifications and substitutions may be made thereto without departing from the spirit and scope of the invention. Accordingly, it is to be understood that the present invention has been described by way of illustrations and not limitation. Embodiments herein can be used independently or can be combined.

All ranges disclosed herein are inclusive of the endpoints, and the endpoints are independently combinable with each other. The ranges are continuous and thus contain every value and subset thereof in the range. Unless otherwise stated or contextually inapplicable, all percentages, when expressing a quantity, are weight percentages. The suffix (s) as used herein is intended to include both the singular and the plural of the term that it modifies, thereby including at least one of that term (e.g., the colorant(s) includes at least one colorants). Option, optional, or optionally means that the subsequently described event or circumstance can or cannot occur, and that the description includes instances where the event occurs and instances where it does not. As used herein, combination is inclusive of blends, mixtures, alloys, reaction products, collection of elements, and the like.

As used herein, a combination thereof refers to a combination comprising at least one of the named constituents, components, compounds, or elements, optionally together with one or more of the same class of constituents, components, compounds, or elements.

All references are incorporated herein by reference.

The use of the terms “a,” “an,” and “the” and similar referents in the context of describing the invention (especially in the context of the following claims) are to be construed to cover both the singular and the plural, unless otherwise indicated herein or clearly contradicted by context. It can further be noted that the terms first, second, primary, secondary, and the like herein do not denote any order, quantity, or importance, but rather are used to distinguish one element from another. It will also be understood that, although the terms first, second, etc. are, in some instances, used herein to describe various elements, these elements should not be limited by these terms. For example, a first current could be termed a second current, and, similarly, a second current could be termed a first current, without departing from the scope of the various described embodiments. The first current and the second current are both currents, but they are not the same condition unless explicitly stated as such.

The modifier about used in connection with a quantity is inclusive of the stated value and has the meaning dictated by the context (e.g., it includes the degree of error associated with measurement of the particular quantity). The conjunction or is used to link objects of a list or alternatives and is not disjunctive; rather the elements can be used separately or can be combined together under appropriate circumstances.

Although the invention has been shown and described with respect to a certain embodiment or embodiments, it is obvious that equivalent alterations and modifications will occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein illustrated exemplary embodiment or embodiments of the invention. In addition, while a particular feature of the invention may have been described above with respect to only one or more of several illustrated embodiments, such feature may be combined with one or more other features of the other embodiments, as may be desired and advantageous for any given or particular application.

What is claimed is:

1. A weighted lock-in detector for signals with arbitrary phase differences, the detector comprising:
a first detection circuit including a first amplifier and a first phase sensitive detector;
a second detection circuit including a second amplifier and a second phase sensitive detector; and
a correlator configured to linearly combine with complex coefficients output signals of the first and second detection circuits, thereby measuring a difference in amplitude between first and second input signals to the respective detection circuits.

2. The weighted lock-in detector for signals with arbitrary phase differences of claim 1, further comprising:
an arbitrary number of channels with individual complex weighing factors.

3. The weighted lock-in detector for signals with arbitrary phase differences of claim 1, further comprising:
a third detection circuit including a third amplifier and a third phase sensitive detector, and
wherein the correlator is configured to linearly combine with complex coefficients output signals of the first, second, and third detection circuits, thereby measuring a difference in amplitude between each pair of input signals to the respective detection circuits.

4. A four-arm bridge comprising:
a first detector node;
a second detector node;
a weighted lock-in detector having a first detection circuit electrically coupled to the first detector node, a second detection circuit electrically coupled to the second detector node, and a correlator configured to linearly combine with complex coefficients output signals of the first and second detection circuits, thereby measuring a difference in amplitude between first and second input signals to the respective detection circuits.

5. A method of lock-in detection for signals having an arbitrary phase difference, the method comprising the steps of:
simultaneously detecting a first input signal and a second input signal through respective detection circuits, generating respective detected signals; and
combining the detected signals linearly with complex coefficients by a correlator, generating an output signal.

6. The method of claim 5, wherein the respective detected signals, E,
$$E = {A}_{o} {e}^{- i φ}$$
and F, are F=Bₒe^{-i(φ+Δ)}, where Aₒ and φ are the amplitude and the phase, respectively, of the first input signal, Bₒ is the amplitude of the second input signal, and Δ is the phase difference between the first input signal and the second input signal.

7. The method of claim 6, wherein the output, D, is D=ρ₁E+ρ₂F=Dₒe^{-iφ}, where Dₒ=Aₒ−Bₒ, ρ₁=1, and ρ₂=e^{jΔ} is determined by a correlator through correlation analysis of the respective detected signals, E and F.

8. The method of claim 5, wherein the output measures difference in amplitude between the first and second input signals and retains common-mode rejection regardless of any phase difference between the first and second input signals.

9. The method of claim 5, wherein detecting a first input signal includes detecting a signal from a first side of a four-arm bridge, detecting a second signal includes detecting a signal from a second side of the four-arm bridge, and wherein the signal from the first side of a four-arm bridge and the signal from the second side of the four-arm bridge are out of phase by approximately 90 degrees.
